(19) United States
(12) Patent Application Publication
(10) Pub. No.: US 2022/0334275 A1
(43) Pub. Date: Oct. 20, 2022

(54) RADIATION DETECTOR

(71) Applicant: SHENZHEN XPECTVISION TECHNOLOGY CO., LTD., Shenzhen (CN)

(72) Inventors: Peiyan CAO, Shenzhen (CN); Yurun LIU, Shenzhen (CN)

(21) Appl. No.: 17/859,523

(22) Filed: Jul. 7, 2022

Related U.S. Application Data
(63) Continuation of application No. PCT/CN2020/076790, filed on Feb. 26, 2020.

(51) Int. Cl. G01T 1/24; H01L 27/146; H01L 31/18

(52) U.S. Cl. CPC G01T 1/24; H01L 27/14659; H01L 27/14661; H01L 27/1469; H01L 31/1892

(57) ABSTRACT

Disclosed herein is a method, comprising: forming a radiation absorption layer comprising a layer of SiC on a semiconductor substrate; forming a first electric contacts on a first surface of the radiation absorption layer; bonding the radiation absorption layer with an electronics layer; removing the semiconductor substrate; forming a second electric contacts on a second surface of the radiation absorption layer distal from the electronics layer.

### TECHNICAL FIELD

The disclosure herein relates to a radiation detector.

### BACKGROUND

Radiation detectors may be devices used to measure the flux, spatial distribution, spectrum or other properties of radiations. Radiation detectors may be used for many applications. One important application is imaging. Radiation imaging is a radiography technique and can be used to reveal the internal structure of a non-uniformly composed and opaque object such as the human body.

Early radiation detectors for imaging include photographic plates and photographic films. A photographic plate may be a glass plate with a coating of light-sensitive emulsion. Although photographic plates were replaced by photographic films, they may still be used in special situations due to the superior quality they offer and their extreme stability. A photographic film may be a plastic film (e.g., a strip or sheet) with a coating of light-sensitive emulsion.

In the 1980s, photostimulable phosphor plates (PSP plates) became available. A PSP plate may contain a phosphor material with color centers in its lattice. When the PSP plate is exposed to radiation, electrons excited by radiation are trapped in the color centers until they are stimulated by a laser beam scanning over the plate surface. As the plate is scanned by laser, trapped excited electrons give off light, which is collected by a photomultiplier tube. The collected light is converted into a digital image. In contrast to photographic plates and photographic films, PSP plates can be reused.

Another kind of radiation detectors are radiation image intensifiers. Components of a radiation image intensifier are usually sealed in a vacuum. In contrast to photographic plates, photographic films, and PSP plates, radiation image intensifiers may produce real-time images, i.e., do not require post-exposure processing to produce images, radiation first hits an input phosphor (e.g., cesium iodide) and is converted to visible light. The visible light then hits a photocathode (e.g., a thin metal layer containing cesium and antimony compounds) and causes emission of electrons. The number of emitted electrons is proportional to the intensity of the incident radiation. The emitted electrons are projected, through electron optics, onto an output phosphor and cause the output phosphor to produce a visible-light image.

Scintillators operate somewhat similarly to radiation image intensifiers in that scintillators (e.g., sodium iodide) absorb radiation and emit visible light, which can then be detected by a suitable image sensor for visible light. In scintillators, the visible light spreads and scatters in all directions and thus reduces spatial resolution. Reducing the scintillator thickness helps to improve the spatial resolution but also reduces absorption of radiation. A scintillator thus has to strike a compromise between absorption efficiency and resolution.

Semiconductor radiation detectors largely overcome this problem by direct conversion of radiation into electric signals. A semiconductor radiation detector may include a semiconductor layer that absorbs radiation in wavelengths of interest. When a particle of radiation is absorbed in the semiconductor layer, multiple charge carriers (e.g., electrons and holes) are generated and swept under an electric field towards electric contacts on the semiconductor layer.

### SUMMARY

Disclosed herein is a method, comprising: forming a radiation absorption layer comprising a layer of SiC on a semiconductor substrate; forming a first electric contacts on a first surface of the radiation absorption layer; bonding the radiation absorption layer with an electronics layer; removing the semiconductor substrate; forming a second electric contacts on a second surface of the radiation absorption layer distal from the electronics layer.

According to an embodiment, the layer of SiC has a thickness up to 10 micrometers.

According to an embodiment, the first electric contact comprises a plurality of discrete regions configured to collect charge carriers from the radiation absorption layer.

According to an embodiment, the plurality of discrete regions of the first electric contact are arranged in an array.

According to an embodiment, the electronics layer comprises an electronic system configured to determine amounts of charge carriers respectively collected by the discrete regions of the first electric contact.

According to an embodiment, the electronic system is configured to determine the amounts of charge carriers collected over a same period of time.

According to an embodiment, the electronic system further comprises an integrator configured to integrate electric currents through the plurality of discrete regions of the first electric contact.

According to an embodiment, the electronic system further comprises a controller configured to connect the first electric contact to an electrical ground.

According to an embodiment, the controller is configured to connect the first electric contact to an electrical ground after a rate of change of the amounts becomes substantially zero.

Disclosed herein is a radiation detector, comprising: a radiation absorption layer comprising a layer of SiC, configured to generate charge carriers in the radiation absorption layer from radiation incident on the radiation absorption layer; an electric contact with a plurality of discrete regions, the electric contact configured to collect the charge carriers from the radiation absorption layer; and an electronic system configured to determine amounts of charge carriers respectively collected by the plurality of discrete regions.

According to an embodiment, the layer of SiC has a thickness up to 10 micrometers.

According to an embodiment, the plurality of discrete regions are arranged in an array.

According to an embodiment, the electronic system is configured to determine the amounts over the same period of time.

According to an embodiment, the electronic system comprises an integrator configured to integrate electric current through the plurality of discrete regions.

According to an embodiment, the radiation detector further comprises a controller configured to connect the electric contact to an electrical ground.

According to an embodiment, the controller is configured to connect the electric contact to the electrical ground after a rate of change of the amounts becomes substantially zero.

According to an embodiment, the radiation detector does not comprise a scintillator.

### BRIEF DESCRIPTION OF FIGURES

FIG. 1A schematically shows a cross-sectional view of a radiation detector, according to an embodiment.

FIG. 1B schematically shows a detailed cross-sectional view of the radiation detector, according to an embodiment.

FIG. 1C schematically shows that a top view of the radiation detector, according to an embodiment.

FIG. 2A-FIG. 2F schematically show a process of making the radiation detector, according to an embodiment.

FIG. 3 schematically shows a component diagram of an electronic system of the radiation detector, according to an embodiment.

### DETAILED DESCRIPTION

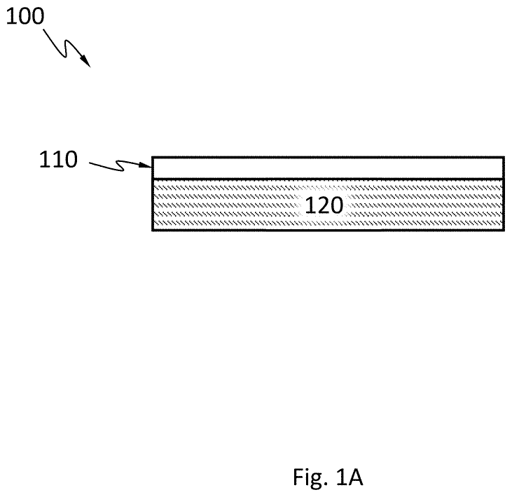

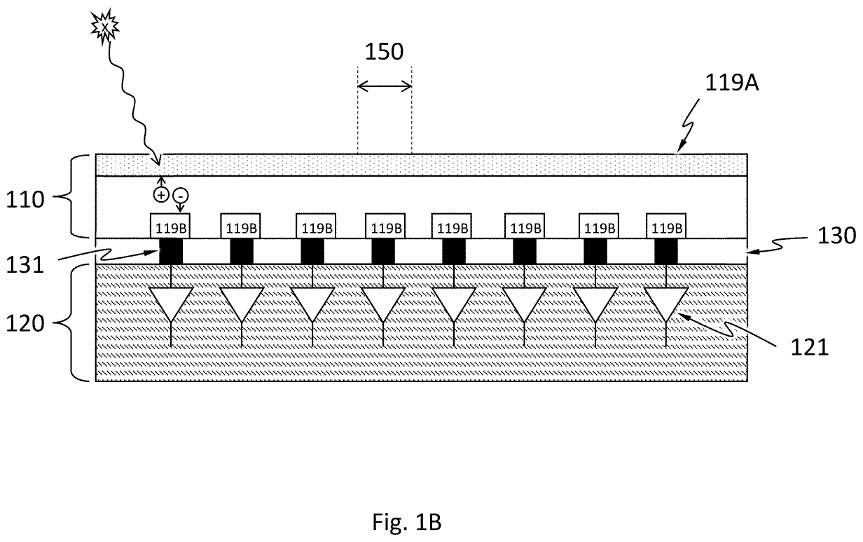

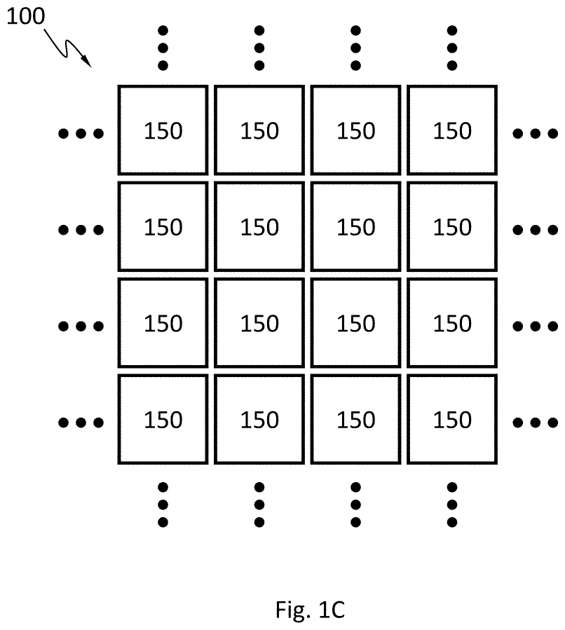

FIG. 1A schematically shows a cross-sectional view of a radiation detector 100, according to an embodiment. The radiation detector 100 may include a radiation absorption layer 110 and an electronics layer 120 (e.g., an ASIC) for processing or analyzing electrical signals. The electrical signals may be incurred by charge carriers generated in the radiation absorption layer 110 from radiation incident on the radiation absorption layer 110. In an embodiment, the radiation detector 100 does not include a scintillator. The radiation absorption layer 110 includes a layer of silicon carbide (SiC). In an example, the layer of SiC may have a thickness up to 10 micrometers.

As shown in a detailed cross-sectional view of the radiation detector 100 in FIG. 1B, according to an embodiment. The radiation absorption layer 110 may include electric contacts (e.g., 119A, 119B as shown in FIG. 1B). The electric contact 119B may have a plurality of discrete regions configured to collect the charge carriers from the radiation absorption layer 110. When a particle of radiation hits the radiation absorption layer 110, it may be absorbed and generate one or more charge carriers by a number of mechanisms. A particle of radiation may generate 10 to 100000 charge carriers. The charge carriers may drift to the electric contact 119A and the electric contact 119B under an electric field. The electric field may be an external electric field. In an embodiment, the charge carriers may drift in directions such that the charge carriers generated by a single particle of radiation are not substantially shared by two different discrete regions of the electric contact 119B (“not substantially shared” here means less than 2%, less than 0.5%, less than 0.1%, or less than 0.01% of these charge carriers flow to a different one of the discrete regions than the rest of the charge carriers). A footprint of the pixel 150 associated with one discrete region of the electric contact 119B may be an area around the discrete region in which substantially all (more than 98%, more than 99.5%, more than 99.9% or more than 99.99% of) charge carriers generated by one particle of radiation incident therein flow to the discrete region of the electric contact 119B. Namely, less than 2%, less than 0.5%, less than 0.1%, or less than 0.01% of these charge carriers flow beyond the pixel 150 associated with the one discrete region of the electric contact 119B. Charge carriers generated by one particle of radiation incident around the footprint of one of the discrete regions of the electric contact 119B are not substantially shared with another discrete region of the electric contact 119B.

FIG. 1C schematically shows that pixels 150 in the radiation detector 100 may be arranged in an array, according to an embodiment. Namely, the plurality of discrete regions of the electric contact 119B may be arranged in an array. The array may be a rectangular array, a honeycomb array, a hexagonal array or any other suitable array.

The electronics layer 120 may include an electronic system 121 suitable for processing electrical signals generated by particles of radiation incident on the radiation absorption layer 110, and determining amounts of the charge carriers respectively collected by the plurality of discrete regions. The electronic system 121 may include an analog circuitry such as a filter network, amplifiers, integrators, and comparators, or a digital circuitry such as a microprocessor, and a memory. The electronic system 121 may include components dedicated to each of the plurality of discrete regions of the electric contact 119B or components shared among the plurality of discrete regions. In one embodiment, the electronics system 121 is configured to determine the amounts the charge carriers respectively collected by the plurality of discrete regions of the electric contact 119B over the same period of time. The electronic system 121 may be electrically connected to the discrete regions of the electric contact 119B by vias 131. Space among the vias may be filled with a filler material 130, which may increase the mechanical stability of the connection of the electronics layer 120 to the radiation absorption layer 110. Other bonding techniques are possible to connect the electronic system 121 to the discrete regions without using vias.

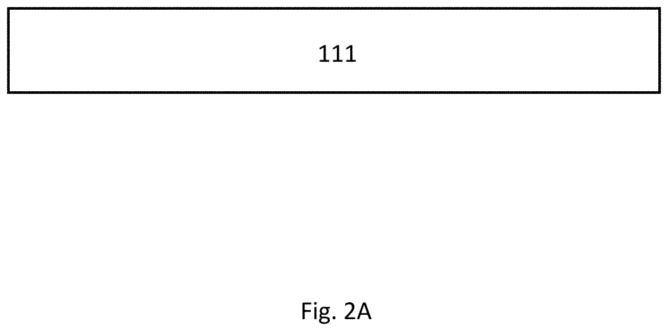

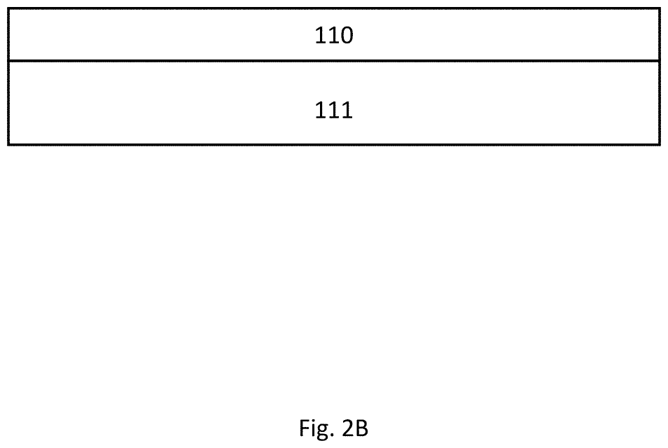

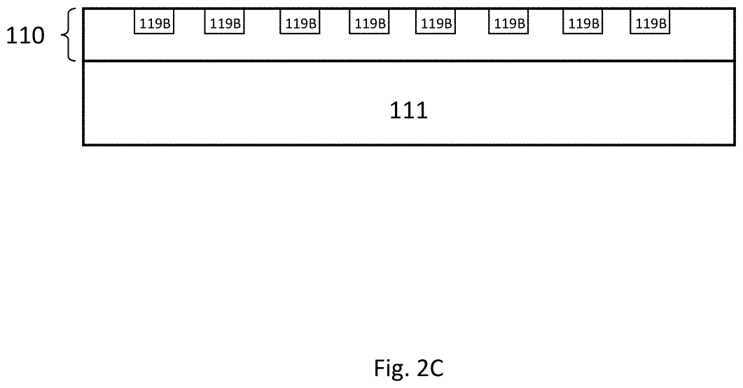

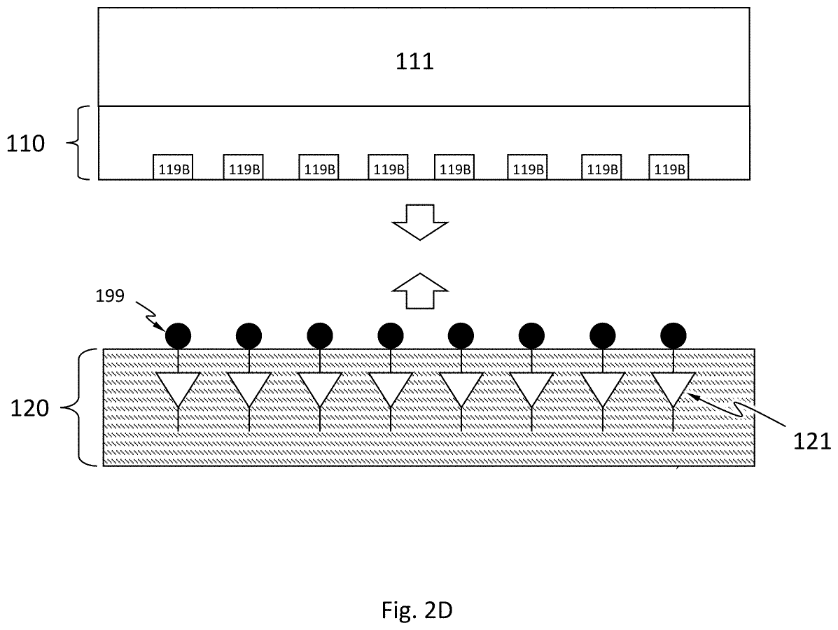

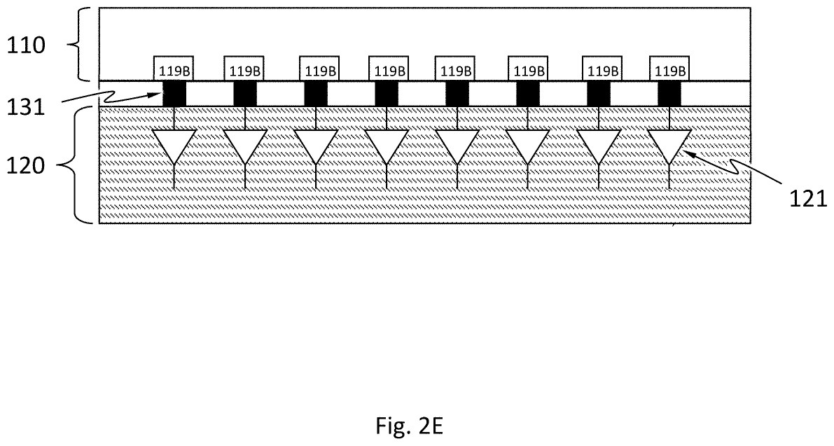

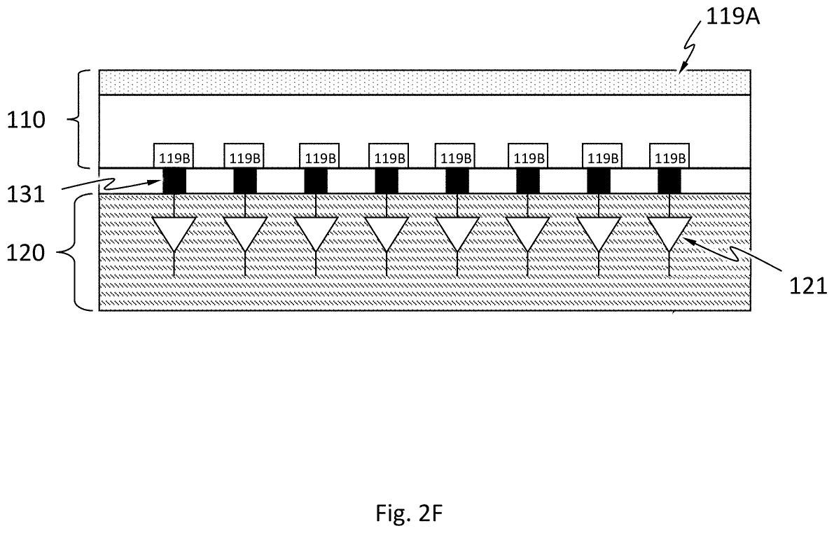

FIG. 2A-FIG. 2F schematically show a process of making the radiation detector 100, according to an embodiment. FIG. 2A schematically shows that the method may start with a semiconductor substrate 111. In one embodiment, the semiconductor substrate 111 includes semiconductor materials such as silicon, germanium, GaAs or a combination thereof.

FIG. 2B schematically shows that the radiation absorption layer 110 is formed on the semiconductor substrate 111, according to an embodiment. The radiation absorption layer 110 may be formed using any suitable technique such as chemical vapor deposition (CVD) and atomic layer deposition (ALD).

FIG. 2C schematically shows the electric contact 119B with a plurality of discrete regions is formed on a surface of the radiation absorption layer 110. The surface on which electric contact 119B is formed may be a surface of the layer of SiC. Namely, the electric contact 119B may be in direct physical contact with the layer of SiC.

FIG. 2D schematically shows that the radiation absorption layer 110, with the electric contact 119B, is bonded to the electronics layer 120 using a suitable bonding method, such as direct bonding or flip chip bonding. Direct bonding is a wafer bonding process without any additional intermediate layers (e.g., solder bumps). The bonding process is based on chemical bonds between two surfaces. Direct bonding may be at elevated temperature but not necessarily so. Flip chip bonding uses solder bumps 199 deposited onto contact pads (e.g., the electrical contact 119B of the radiation absorption layer 110), as shown in FIG. 2D. The radiation absorption layer 110 is bonded to the electronics layer 120 so that the electric contact 119B is connected to the electronic system 121 in the electronics layer 120.

FIG. 2E schematically shows that, after bonding the radiation absorption layer 110 to the electronics layer 120, the semiconductor substrate 111 is removed using a suitable method, such as grinding or etching.

FIG. 2F schematically shows that the electric contact 119A is formed on a surface of the radiation absorption layer 110 that is distal from the electronics layer 120. The surface on which the electric contact 119A is formed may be a surface of the layer of SiC. Namely, the electric contact 119A may be in direct physical contact with the layer of SiC.

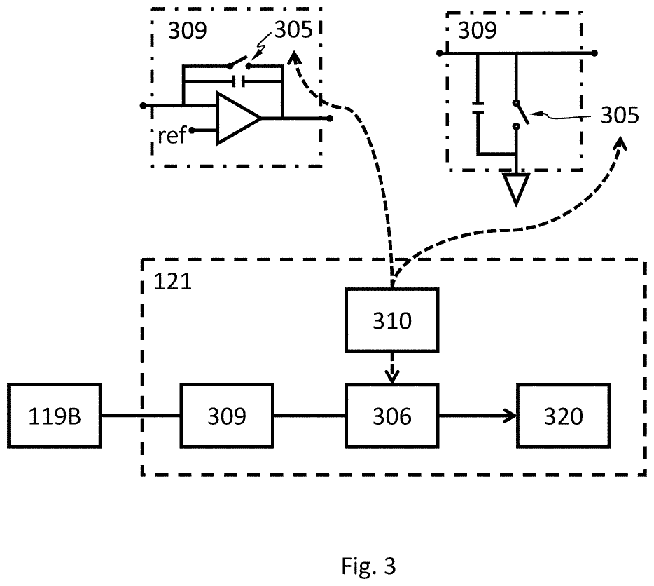

FIG. 3 shows a functional block diagram of the electronic system 121, according to an embodiment. The electronic system 121 may include a memory 320, a voltmeter 306, an integrator 309, and a controller 310.

The controller 310 may be configured to connect the electric contact 119B to an electrical ground, so as to discharge any charge carriers accumulated on the electric contact 119B. In an embodiment, the electric contact 119B is connected to an electrical ground after a rate of change of the amounts of charge carriers respectively collected by the discrete regions of the electric contact 119B becomes substantially zero. The rate of change of the amounts being substantially zero means that temporal change of the amounts is less than 0.1%/ns. In an embodiment, the electric contact 119B is connected to an electrical ground for a finite reset time period. The controller 310 may connect the electric contact 119B to the electrical ground by controlling a reset switch 305. The reset switch 305 may be a transistor such as a field-effect transistor (FET).

The voltmeter 306 may feed the voltage it measures to the controller 310 as an analog or digital signal.

In an example, the integrator 309 is configured to integrate electric current through the plurality of discrete regions of the electric contact 119B. The integrator 309 may include an operational amplifier with a capacitor feedback loop (e.g., between the inverting input and the output of the operational amplifier). The integrator 309 is electrically connected to the electric contact 199B and is configured to integrate the electric current (i.e., the charge carriers collected by the electric contact) flowing through the discrete regions of electric contact 119B over a period time. The integrator 309 may be configured as a capacitive transimpedance amplifier (CTIA). CTIA has high dynamic range by keeping the amplifier from saturating and improves the signal-to-noise ratio by limiting the bandwidth in the signal path. Charge carriers from the electric contact 119B accumulate on a capacitor and are integrated over a period of time (“integration period”). After the integration period has expired, the voltage across the capacitor may be sampled and then the capacitor may be reset by the reset switch 305. The integrator 309 may include a capacitor directly connected to the electric contact 119B. In an example, the integration period expires when a rate of change of the amounts of charge carriers respectively collected by the discrete regions of the electric contact 119B becomes substantially zero.

The memory 320 may be configured to store data such as the amounts of charge carriers.

The controller 310 may be configured to cause the voltmeter 306 to measure a voltage from the integrator 309 representing the amounts of charge carriers integrated by the integrator 309 (e.g., the voltage across the capacitor in the integrator 309). The controller 310 may be configured to determine the amounts of charge carriers based on the voltage.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

1. A method comprising:
forming a radiation absorption layer comprising a layer of SiC on a semiconductor substrate;
forming a first electric contact on a first surface of the radiation absorption layer;
bonding the radiation absorption layer with an electronics layer;
removing the semiconductor substrate;
forming a second electric contact on a second surface of the radiation absorption layer distal from the electronics layer.

2. The method of claim 1, wherein the layer of SiC has a thickness up to 10 micrometers.

3. The method of claim 1, wherein the first electric contact comprises a plurality of discrete regions configured to collect charge carriers from the radiation absorption layer.

4. The method of claim 3, wherein the plurality of discrete regions of the first electric contact are arranged in an array.

5. The method of claim 3, wherein the electronics layer comprises an electronic system configured to determine amounts of charge carriers respectively collected by the discrete regions of the first electric contact.

6. The method of claim 5, wherein the electronic system is configured to determine the amounts of charge carriers collected over a same period of time.

7. The method of claim 5, wherein the electronic system further comprises an integrator configured to integrate electric currents through the plurality of discrete regions of the first electric contact.

8. The method of claim 5, wherein the electronic system further comprises a controller configured to connect the first electric contact to an electrical ground.

9. The method of claim 8, wherein the controller is configured to connect the first electric contact to an electrical ground after a rate of change of the amounts becomes substantially zero.

10. A radiation detector comprising:
a radiation absorption layer comprising a layer of SIC, configured to generate charge carriers in the radiation absorption layer from radiation incident on the radiation absorption layer;
an electric contact with a plurality of discrete regions, the electric contact configured to collect the charge carriers from the radiation absorption layer; and
an electronic system configured to determine amounts of charge carriers respectively collected by the plurality of discrete regions.

11. The radiation detector of claim 10, wherein the layer of SiC has a thickness up to 10 micrometers.

12. The radiation detector of claim 10, wherein the plurality of discrete regions are arranged in an array.

13. The radiation detector of claim 10, wherein the electronic system is configured to determine the amounts over the same period of time.

14. The radiation detector of claim 10, wherein the electronic system comprises an integrator configured to integrate electric current through the plurality of discrete regions.

15. The radiation detector of claim 10, further comprising a controller configured to connect the electric contact to an electrical ground.

16. The radiation detector of claim 15, wherein the controller is configured to connect the electric contact to the electrical ground after a rate of change of the amounts becomes substantially zero.

17. (canceled)

18. The method of claim 1, wherein forming the first electric contact is before removing the semiconductor substrate.

19. The method of claim 1, wherein the first surface is opposite from the semiconductor substrate.

20. The method of claim 1, wherein removing the semiconductor substrate exposes the second surface.

21. The method of claim 1, wherein bonding the radiation absorption layer is before removing the semiconductor substrate and forming the second electric contact.
